(19) United States
(12) Patent Application Publication
(10) Pub. No.: US 2008/0174387 A1
(43) Pub. Date: Jul. 24, 2008

(54) FILTER CIRCUIT FOR REDUCING EMI OF DIFFERENTIAL SIGNAL

(75) Inventor: Chin-Chun Chiang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ASUSTEK COMPUTER INC., Taipei (TW)

(21) Appl. No.: 11/971,888

(22) Filed: Jan. 9, 2008

(30) Foreign Application Priority Data
Jan. 18, 2007 (TW) 96101887

(51) Int. Cl. H03H 7/06

(52) U.S. Cl. 333/167

(57) ABSTRACT

A filter circuit for reducing electro magnetic interference (EMI) of a differential signal is disclosed. The circuit includes a first passive component set, a second passive component set, and a third passive component set. The first passive component set has a first input/output side and a second input/output side. The second passive component set is disposed between a positive signal end and a negative signal end of the first input/output side, and the third passive component set is disposed between a positive signal end and a negative signal end of the second input/output side. According to the circuit of the present invention, EMI of the differential signal can be reduced and signal-transmission-speed may not be reduced.

### CROSS-REFERENCE TO RELATED APPLICATION

This application claims the priority benefit of Taiwan application serial no. 96101887, filed on Jan. 18, 2007. The entirety of the above-mentioned patent application is hereby incorporated by reference herein and made a part of this specification.

### BACKGROUND OF THE INVENTION

1. Field of the Invention

The invention relates to a signal processing device and, more particularly, to a filter circuit for reducing electro magnetic interference (EMI) of a differential signal.

2. Description of the Related Art

In the valuation standards of all kinds of electrical devices, electro magnetic compatibility (EMC) is a key quality indicator for a personal computer, a television, audio equipment, and so on. In the modern developed countries, the valuation reports on EMC are paid more and more attention to. The signal-transmission-speed of the electrical devices is faster and faster, and therefore electro magnetic interference (EMI), which is produced by the electrical components disposed in the electrical devices, is more and more serious to affect the normal operation of the electrical devices.

The valuation on EMC includes the EMI and electro magnetic susceptibility (EMS). The EMI is transmitted either by conduction or by radiation, while EMI radiation is usually blocked by changing the circuits or the configuration of the components. In the conventional art, in order to reduce the effect of the EMI, designers usually use capacitors, resistors, inductors, and so on, or even ferrite beads in cooperative with circuit designs, such as L-shape, T-shape, π-shape, to constitute a filter circuit against the EMI.

FIG. 1 is a configuration diagram showing a conventional combined anti-EMI filter circuit. In FIG. 1, there is an L-shape filter, a T-shaped filter, and a π-shape filter. All of these filters include capacitors (C) and inductors (L), and therefore they are also called composite LC-shape filters. The filters, according to the design principle of the Butterworth filter or the Chebyshev filter and the characteristics of high-frequency-conduction and low-frequency-blocking of the capacitors and low-frequency-conduction and high-frequency-blocking of the inductor, combine the capacitors with the inductors to constitute the circuits with certain filter function. However, in the combined anti-EMI filters, the capacitors and the inductors are easily affected at high frequency by the distributed parameters even to cause resonance then to reduce the performance of insertion loss quickly. Therefore the filters are only suitable for blocking the interfere of the relative low frequency.

The conventional art is only suitable for blocking the interfere of the relative low frequency, and therefore it is impossible to completely and effectively reduce the EMI for many electrical devices. Further the circuit configuration in the conventional art may reduce the signal-transmission-speed then to delay the system operation and decrease the system efficiency.

### BRIEF SUMMARY OF THE INVENTION

It is therefore an objective of the invention to provide a filter circuit employing passive component sets in cooperative with circuit designs to improve the electro magnetic interference (EMI) problems, and choosing suitable devices to minimize the EMI effect according to the characteristics of input signals.

The invention provides a filter circuit including a first passive component set, a second passive component set, and a third passive component set. The first passive component set has a first input/output side and a second input/output side, and both the first input/output side and the second input/output side respectively have a positive signal end and a negative signal end. The positive signal end and the negative signal end of the first input/output side are coupled to each other via the second passive component set. The positive signal end and the negative signal end of the second input/output side are coupled to each other via the third passive component set.

In a preferred embodiment, the first passive component set may include a first passive component and a second passive component. A first end and a second end of the first passive component may be correspondingly coupled to the positive signal end of the first input/output side and that of the second input/output side, and a first end and a second end of the second passive component may be correspondingly coupled to the negative signal end of the first input/output side and that of the second input/output side.

The second passive component set may be disposed between the positive signal end and the negative signal end of the first input/output side, and may include a third passive component and a fourth passive component. One end of the fourth passive component may be coupled to the positive signal end of the first input/output side via the third passive component, and the other end of the fourth passive component may be coupled to the negative signal end of the first input/output side. The third passive component set may be disposed between the positive signal end and the negative signal end of the second input/output side, and may include a fifth passive component and a sixth passive component. One end of the sixth passive component may be coupled to the positive signal end of the second input/output side via the fifth passive component, and the other end of the sixth passive component may be coupled to the negative signal end of the second input/output side.

Further, the invention provides a filter circuit including a first passive component, a second passive component, a third passive component, a fourth passive component, a first capacitor, and a second capacitor. One end of the first capacitor is coupled to the first end of the first passive component, and the other end is coupled to the first end of the second passive component via the third passive component. One end of the second capacitor is coupled to the second end of the first passive component, and the other end is coupled to the second end of the second passive component via the fourth passive component.

In a preferred embodiment, the first passive component and the second passive component may include one kind of choke coils, inductors, resistors, and ferrite beads, and the third passive component and the fourth passive component may include one kind of inductors, resistors, and ferrite beads. When the passive components are resistors, the resistance values of the resistors may be between 1 and 330 ohms; when the passive components are ferrite beads, the resistance values of the ferrite beads may be between 10 and 330 ohms. The capacitance values of the first capacitor and the second capacitor may be between 3 and 330 picofarads.

The invention employs the passive component sets for receiving a differential signal, so that when the EMI produced by the input signals passes the passive component sets, the EMI can be counterbalanced by each other due to the induction magnetic field to be effectively reduced. Further, the invention employs the series connection for the passive component sets to prevent the input signals from directly flowing into the capacitors, so that the signals can pass fast to solve the problem of system delays due to the slow transmission of the signals.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1 is a configuration diagram showing a conventional combined anti-EMI filter circuit.

FIG. 2 is a configuration diagram showing a filter circuit according to a preferred embodiment of the invention.

FIG. 3A is a discrete signal diagram of digital visual interface (DVI) when a filter circuit is not used.

FIG. 3B is a discrete signal diagram of digital visual interface (DVI) when a filter circuit is used.

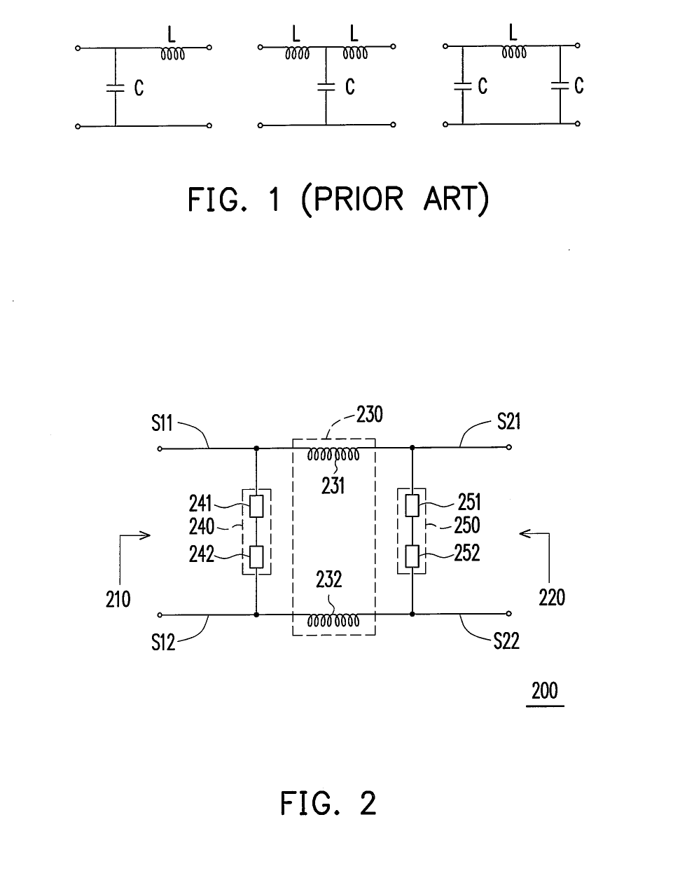

### DETAILED DESCRIPTION OF THE EMBODIMENTS

FIG. 2 is a configuration diagram showing a filter circuit 200 according to a preferred embodiment of the invention. In FIG. 2, the filter circuit 200 includes a passive component set 230, a passive component set 240, and a passive component set 250. The passive component set 230 has input/output sides 210 and 220 for receiving or outputting a differential signal, respectively. Furthermore, the input/output sides both have a positive signal end, such as S11 and S21, and a negative signal end, such as S12 and S22. The positive signal end S11 and the negative signal end S12 are coupled to each other via the passive component set 240. The positive signal end S21 and the negative signal end S22 are coupled to each other via the passive component set 250.

The passive component set 230 may include passive components 231 and 232. The first end and the second end of the passive component 231 are correspondingly coupled to the positive signal ends S11 and S21, and the first end and the second end of the passive component 232 are correspondingly coupled to the negative signal ends S12 and S22.

In general, the passive components 231 and 232 may be choke coils, resistors, inductors, or ferrite beads. In this embodiment, both the passive component 231 and the passive component 232 are the choke coils, but the invention is not limited thereto.

Furthermore, the passive component set 240 may also include passive components 241 and 242. One end of the passive component 241 is coupled to the positive signal end S11, and the other end is coupled to the negative signal end S12 via the fourth passive component 242. In this embodiment, the passive component 241 may be a resistor, an inductor, or a ferrite bead, while the passive component 242 may be a capacitor.

In a preferred embodiment, when the passive component 241 is a resistor, the resistance value may be between 1 and 330 ohms. When the passive component 241 is a ferrite bead, the resistance value may be between 10 and 330 ohms. Furthermore, when the passive components 242 and 252 are capacitors, the capacitance values may be between 3 and 330 picofarads.

Similar to the passive component set 240, the passive component set 250 includes passive components 251 and 252. One end of the passive component 251 is coupled to the second positive signal end S21, and the other end of the passive component 251 is coupled to the negative signal end S22 via the passive component 252.

Although the above has provided the structure of the preferred embodiments of the invention, persons having ordinary skill in the art can know that the arrangements of the devices in the passive component sets 240 and 250 in this embodiment are not limited thereto. That is, the positions of the passive components can be exchanged, which may not affect the spirit of the invention.

Especially the invention does not have a limitation that the input/output sides 210 or 220 is used to receive or output a differential signal. That is, when the input/output side 210 is a signal-receiving end, the input/output side 220 is a signal-outputting end, and vice versa. The filter circuit 200 according to the preferred embodiment can process the differential signal of an electrical device or a circuit according to the requirements of a user. For example, the preferred embodiment of the invention can process the differential signal output by a digital visual interface (DVI) connector, a local area network connector, a universal serial bus connector, an IEEE 1394 connector, or a low-voltage connector. Furthermore, the preferred embodiment of the invention can also be used to process the differential signal produced by a high-speed chip.

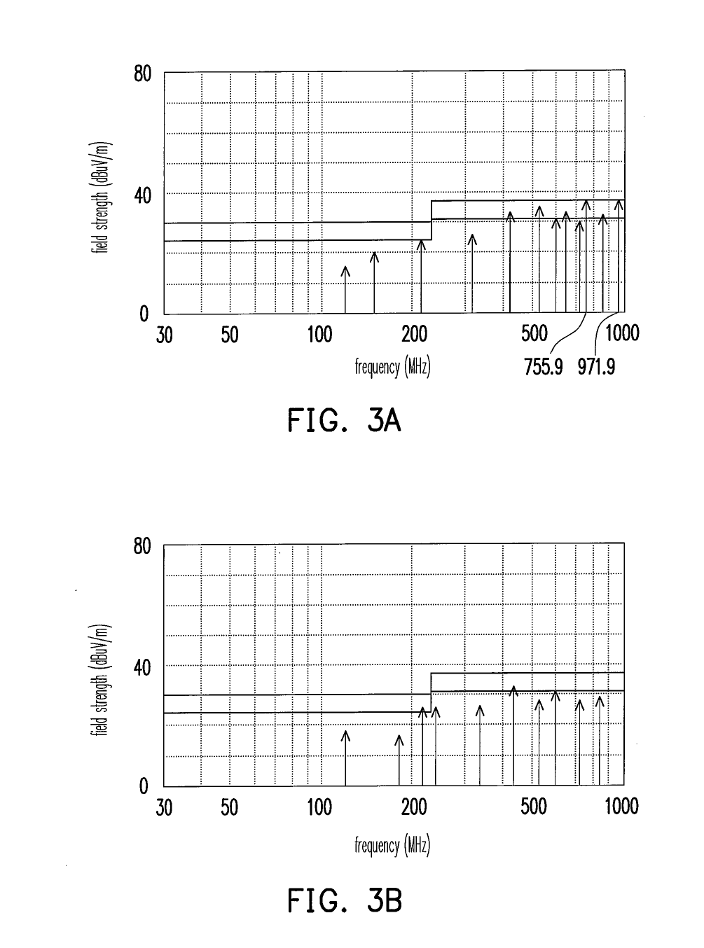

FIG. 3A is a discrete signal diagram of digital visual interface (DVI) when the filter circuit 200 is not used. FIG. 3B is a discrete signal diagram of digital visual interface (DVI) when the filter circuit 200 is used. Please refer to FIG. 3A and FIG. 3B together. At the places where the frequencies are 755.9 and 971.9 megahertz in FIG. 3A, the signals exceed the standard level, while the signals are obviously improve in FIG. 3B.

As described above, the filter circuit according to the preferred embodiment of the invention employs passive component sets so that when the EMI produced by input signals passes the passive component sets, the EMI can be counterbalanced by each other due to the induction magnetic field to be effectively reduced and to avoid the abnormal operation of the electrical devices.

Furthermore, due to the small amplitude and the short charging and discharging time, high-speed signals can transmit fast. Therefore the embodiments of the invention employ the second passive component set and the third passive component set to prevent the input signals from directly flowing into the capacitors increasing the charging and discharging time then to cause reduction of the transmission speed and system delays. Therefore the problem of the reduction of the signal-transmission-speed can be solved.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A filter circuit, comprising:
a first passive component set having a first input/output side and a second input/output side, wherein the first input/output side has a first positive signal end and a first negative signal end, and the second input/output side has a second positive signal end and a second negative signal end;
a second passive component set disposed between the first positive signal end and the first negative signal end; and
a third passive component set disposed between the second positive signal end and the second negative signal end.

2. The filter circuit according to claim 1, wherein the first passive component set comprises:
a first passive component, wherein one end of the first passive component is coupled to the first positive signal end of the first input/output side and the other end of the first passive component is coupled to the second positive signal end of the second input/output side; and
a second passive component, wherein one end of the second passive component is coupled to the first negative signal end and the other end of the second passive component is coupled to the second negative signal end of the second input/output side.

3. The filter circuit according to claim 2, wherein the first passive component and the second passive component are choke coils, inductors, resistors, or ferrite beads.

4. The filter circuit according to claim 1, wherein the second passive component set comprises:
a third passive component; and
a fourth passive component, wherein one end of the fourth passive component is coupled to the first positive signal end via the third passive component, and the other end of the fourth passive component is coupled to the first negative signal end.

5. The filter circuit according to claim 4, wherein the third passive component is a resistor, an inductor, or a ferrite bead.

6. The filter circuit according to claim 4, wherein the fourth passive component is a capacitor.

7. The filter circuit according to claim 1, wherein the third passive component set comprises:
a fifth passive component; and
a sixth passive component, wherein one end of the sixth passive component is coupled to the positive signal end of the second input/output side via the fifth passive component, and the other end of the sixth passive component is coupled to the negative signal end of the second input/output side.

8. The filter circuit according to claim 7, wherein the fifth passive component is a resistor, an inductor, or a ferrite bead.

9. The filter circuit according to claim 7, wherein the sixth passive component is a capacitor.

10. The filter circuit according to claim 1, wherein a differential signal is received from one of the first input/output side and the second input/output side.

11. The filter circuit according to claim 10, wherein the differential signal is a digital visual interface (DVI) signal, a local area network signal, a universal serial bus signal, an IEEE 1394 signal, or a low-voltage differential signal.

12. A filter circuit, comprising:
a first passive component;
a second passive component;
a third passive component;
a fourth passive component;
a first capacitor, wherein one end of the first capacitor is coupled to the first end of the first passive component and the other end of the first capacitor is coupled to the first end of the second passive component via the third passive component; and
a second capacitor, wherein one end of the second capacitor is coupled to the second end of the first passive component and the other end of the second capacitor is coupled to the second end of the second passive component via the fourth passive component.

13. The filter circuit according to claim 12, wherein the first passive component and the second passive component are choke coils, inductors, resistors, or ferrite beads.

14. The filter circuit according to claim 12, wherein the first ends of the first passive component and the second passive component receive a differential signal.

15. The filter circuit according to claim 12, wherein the second ends of the first passive component and the second passive component receive a differential signal.

16. The filter circuit according to claim 12, wherein the third passive component and the fourth passive component are resistors.

17. The filter circuit according to claim 16, wherein the resistance values of the resistors are between 1 and 330 ohms.

18. The filter circuit according to claim 12, wherein the third passive component and the fourth passive component are ferrite beads.

19. The filter circuit according to claim 18, wherein the resistance values of the ferrite beads are between 10 and 330 ohms.

20. The filter circuit according to claim 12, wherein the third passive component and the fourth passive component are inductors.
